(19) United States
(12) Patent Application Publication
(10) Pub. No.: US 2024/0215401 A1
(43) Pub. Date: Jun. 27, 2024

(54) DISPLAY MODULE AND ELECTRIC DEVICE INCLUDING THE SAME

(71) Applicant: Samsung Display Co., LTD., Yongin-si (KR)

(72) Inventors: OHJEONG KWON, Yongin-si (KR); SU JEONG KIM, Yongin-si, (KR); TAEHO KIM, Yongin-si (KR); HONGYEON LEE, Yongin-si (KR); SEUNGYEON JEONG, Yongin-si, (KR)

(73) Assignee: Samsung Display Co., LTD., Yongin-si (KR)

(21) Appl. No.: 18/456,545

(22) Filed: Aug. 28, 2023

(30) Foreign Application Priority Data
Dec. 27, 2022 (KR) 10-2022-0186336

(51) Int. Cl. H10K 59/80; H10K 59/35

(52) U.S. Cl. CPC H10K 59/875; H10K 59/35; H10K 59/12

(57) ABSTRACT

A display module includes a display panel including a silicon substrate including pixel areas, a driving circuit layer disposed on the silicon substrate, a light emitting layer disposed on the driving circuit layer and extending over the pixel areas continuously, and a color filter disposed in the pixel areas on the light emitting layer, a phase retardation plate disposed on the display panel, and a wire grid polarizer disposed on the phase retardation plate and including metal patterns spaced apart from each other at selectable intervals.

### CROSS-REFERENCE TO RELATED APPLICATION(S)

This application claims priority to and benefits of Korean Patent Application No. 10-2022-0186336 under 35 U.S.C. § 119, filed on Dec. 27, 2022 in the Korean Intellectual Property Office, the entire contents of which are incorporated herein by reference.

### BACKGROUND

### 1. Technical Field

Embodiments generally relate to a display module. For example, embodiments provide a display module and an electric device including the same.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

Recently, a head mounted display (HMD) including such a display device has been developed. The head mounted display is a virtual reality (VR) or augmented reality (AR) glasses-type monitor device that is worn in the form of glasses or a helmet and focuses on a distance close to the user's eyes. The head mounted display may provide an image displayed on the display device to the user's eyes through a lens.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display module with improved light efficiency.

Embodiments provide an electric device including the display module.

A display module according to embodiments may include a display panel including: a silicon substrate including pixel areas; a driving circuit layer disposed on the silicon substrate; a light emitting layer disposed on the driving circuit layer and extending over the pixel areas continuously; and a color filter disposed in the pixel areas on the light emitting layer; a phase retardation plate disposed on the display panel; and a wire grid polarizer disposed on the phase retardation plate and including metal patterns spaced apart from each other at selectable intervals.

In an embodiment, the phase retardation plate may include a λ/4 phase retardation plate.

In an embodiment, the display module may further include a cover window disposed on the display panel.

In an embodiment, the cover window may be disposed on the wire grid polarizer.

In an embodiment, the cover window may be disposed between the phase retardation plate and the wire grid polarizer.

In an embodiment, the cover window may be disposed between the color filter and the phase retardation plate.

In an embodiment, the color filter may include a first color filter disposed in a first pixel area among the pixel areas and that transmits red light; a second color filter disposed in a second pixel area among the pixel areas and that transmits green light; and a third color filter disposed in a third pixel area among the pixel areas and that transmits blue light.

In an embodiment, the display module may further include a planarization layer disposed between the phase retardation plate and the wire grid polarizer. A first thickness of the first color filter may be thicker than a second thickness of the second color filter and the second thickness of the second color filter may be thicker than the third thickness of the third color filter.

In an embodiment, the second thickness of the second color filter may be in a range of about 1.1 to about 1.1 times the third thickness of the third color filter and the first thickness of the first color filter may be in a range of about 1.3 to about 1.5 times the third thickness of the third color filter.

In an embodiment, the light emitting layer may include a light emitting material that emits white light.

A display module according to embodiments may include a display panel including: a silicon substrate including a first pixel area, a second pixel area, and a third pixel area; a driving circuit layer disposed on the silicon substrate; and a first light emitting layer; a second light emitting layer; and a third light emitting layer disposed in the first pixel area, the second pixel area, and the third pixel area on the driving circuit layer, respectively; a phase retardation plate disposed on the display panel; and a wire grid polarizer disposed on the phase retardation plate and including metal patterns spaced apart from each other at selectable intervals.

In an embodiment, the phase retardation plate may include a λ/4 phase retardation plate.

In an embodiment, the display module may further include a cover window disposed on the display panel.

In an embodiment, the cover window may be disposed on the wire grid polarizer.

In an embodiment, the cover window may be disposed between the phase retardation plate and the wire grid polarizer.

In an embodiment, the cover window may be disposed between the display panel and the phase retardation plate.

In an embodiment, the first light emitting layer may include a light emitting material that emits red light, the second light emitting layer may include a light emitting material that emits green light, and the third light emitting layer may include a light emitting material that emits blue light.

An electric device according to embodiments may include an eyepiece and a display module accommodating portion including a display module that provides an image to the eyepiece. The display module accommodating portion may include a display panel including: a silicon substrate including pixel areas; a driving circuit layer disposed on the silicon substrate; a light emitting layer disposed on the driving circuit layer and extending over the pixel areas continuously, and a color filter disposed in the pixel areas on the light emitting layer; a wire grid polarizer disposed between the eyepiece and the display panel and including metal patterns spaced apart from each other at selectable intervals; a first λ/4 phase retardation plate disposed between the wire grid polarizer and the display panel and adjacent to the wire grid polarizer; a second λ/4 phase retardation plate disposed between the display panel and the eyepiece; a reflective polarizer disposed between the second λ/4 phase retardation plate and the eyepiece; a third λ/4 phase retardation plate disposed between the reflective polarizer and the second λ/4 phase retardation plate[ and a semi-transmissive plate disposed between the second λ/4 phase retardation plate and the third λ/4 phase retardation plate.

In an embodiment, the first λ/4 phase retardation plate may contact a surface of the display panel, the wire grid polarizer may contact a surface of the first λ/4 phase retardation plate, and the reflective polarizer may contact a surface of the display panel.

In an embodiment, the wire grid polarizer may contact a surface of the eyepiece and the first λ/4 phase retardation plate may be disposed between the wire grid polarizer and the reflective polarizer.

A display module and an electronic device including the same according to an embodiment may include a display panel including a silicon substrate, a λ/4 phase retardation plate disposed on the display panel, and a wire grid polarizer disposed on the λ/4 phase retardation plate and including metal patterns spaced apart from each other at selectable intervals. An absorbing polarizer that blocks some of the light emitted from a light emitting layer may not be disposed on the display panel. Accordingly, light efficiency of the display module may be improved by recycling some of the light emitted from the light emitting layer without being blocked.

### BRIEF DESCRIPTION OF THE DRAWINGS

Illustrative, non-limiting embodiments will be more clearly understood from the following detailed description in conjunction with the accompanying drawings in which:

FIG. 1 is a schematic plan view illustrating a display module according to an embodiment.

FIG. 2 is a schematic cross-sectional view taken along line I-I′ of FIG. 1.

FIG. 3 is a schematic cross-sectional view illustrating recycled light generated in the display module of FIG. 2.

FIGS. 4, 5, 6, 7, and 8 are schematic cross-sectional views for explaining a manufacturing method of the display module of FIG. 2.

FIGS. 9, 10, and 11 are schematic cross-sectional views illustrating a display module according to an embodiment.

FIGS. 12, 13, and 14 are schematic cross-sectional views illustrating a display module according to an embodiment.

FIGS. 15 and 16 are perspective views illustrating an electronic device according to an embodiment.

FIG. 17 is a side view illustrating an example of a display module accommodating portion of the electronic device of FIGS. 15 and 16.

FIG. 18 is a side view illustrating another example of a display module accommodating portion of the electronic device of FIGS. 15 and 16.

### DETAILED DESCRIPTION OF THE EMBODIMENTS

Hereinafter, a display module and an electric device including the same according to embodiments will be explained in detail with reference to the accompanying drawings. The same reference numerals are used for the same components in the drawings, and redundant descriptions of the same components may be omitted.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.

In the specification and the claims, the phrase “at least one of” is intended to include the meaning of “at least one selected from the group of” for the purpose of its meaning and interpretation. For example, “at least one of A and B” may be understood to mean “A, B, or A and B.

In the disclosure, it will be understood that when an element or layer is referred to as being “on”, “connected to” or “coupled to” another element or layer, it can be directly on, connected or coupled to the other element or layer or intervening elements or layers may be present.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

As used herein, the singular forms, “a,” “an,” and “the” are intended to include the plural forms as well, unless the context clearly indicates otherwise.

Unless explicitly described to the contrary, “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Embodiments described in the disclosure are described with reference to schematic plan views and schematic cross-sectional views that are illustrated schematic diagrams. Accordingly, shapes of the views may vary depending on manufacturing technologies and/or tolerances. Thus, embodiments are not limited to illustrated forms and also include variations in form produced according to manufacturing processes. Therefore, regions illustrated in the drawings are examples, and the shapes of the regions illustrated in the drawings are intended to illustrate the example shapes of the regions of elements and not to limit the scope of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

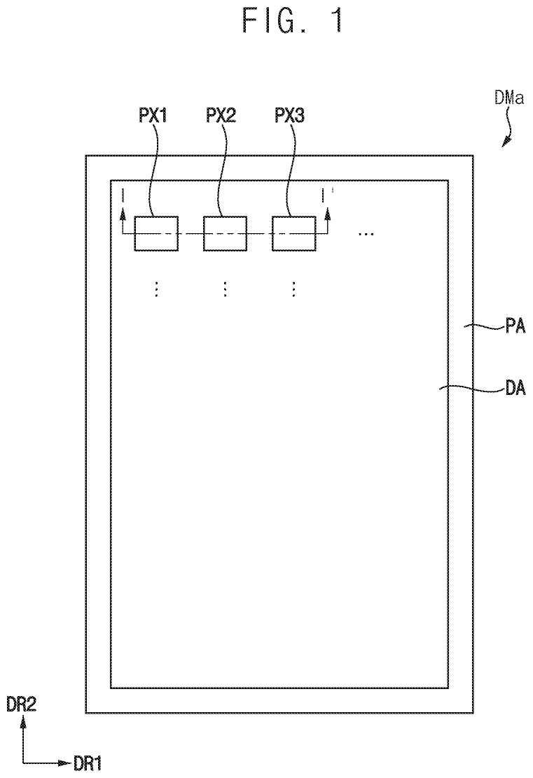

FIG. 1 is a schematic plan view illustrating a display module according to an embodiment.

Referring to FIG. 1, a display module DMa according to an embodiment may include a display area DA and a peripheral area PA. The display area DA may be an area capable of displaying an image by generating light or adjusting transmittance of light provided from an external light source. The peripheral area PA may be an area not displaying an image. The peripheral area PA may be positioned around the display area DA. For example, the peripheral area PA may entirely surround or may be adjacent to the display area DA.

The display area DA may include pixel areas. The pixel areas may be arranged or disposed in a matrix form along a first direction DR1 and a second direction DR2 intersecting the first direction DR1. For example, the pixel areas may include a first pixel area PX1, a second pixel area PX2, and a third pixel area PX3.

Each of the first pixel area PX1, the second pixel area PX2, and the third pixel area PX3 may refer to an area in which light emitted from a light emitting element is emitted to the outside of the display module DMa. For example, the first pixel area PX1 may emit first light, the second pixel area PX2 may emit second light, and the third pixel area PX3 may emit third light. In an embodiment, the first light may be red light, the second light may be green light, and the third light may be blue light. However, the disclosure is not limited thereto. For example, the first, second, and third pixel areas PX1, PX2, and PX3 may be combined to emit yellow, cyan, and magenta lights.

The first, second, and third pixel areas PX1, PX2, and PX3 may emit light of four or more colors. For example, the first, second, and third pixel areas PX1, PX2, and PX3 may be combined to further emit at least one of yellow, cyan, and magenta lights in addition to red, green, and blue lights. The first, second, and third pixel areas PX1, PX2, and PX3 may be combined to further emit white light.

Each of the first pixel area PX1, the second pixel area PX2, and the third pixel area PX3 may have a triangular planar shape, a quadrangular planar shape, a circular planar shape, a track-shaped planar shape, an elliptical planar shape, or the like within the spirit and the scope of the disclosure. In an embodiment, each of the first pixel area PX1, the second pixel area PX2, and the third pixel area PX3 may have a rectangular planar shape. However, the disclosure is not limited thereto, and each of the first pixel area PX1, the second pixel area PX2, and the third pixel area PX3 may have a different planar shape.

The display module DMa may have a rectangular planar shape. However, the disclosure is not limited thereto, and the display module DMa may have various planar shapes.

In this specification, a plane may be defined as the first direction DR1 and the second direction DR2 intersecting the first direction DR1. For example, the first direction DR1 may be perpendicular to the second direction DR2.

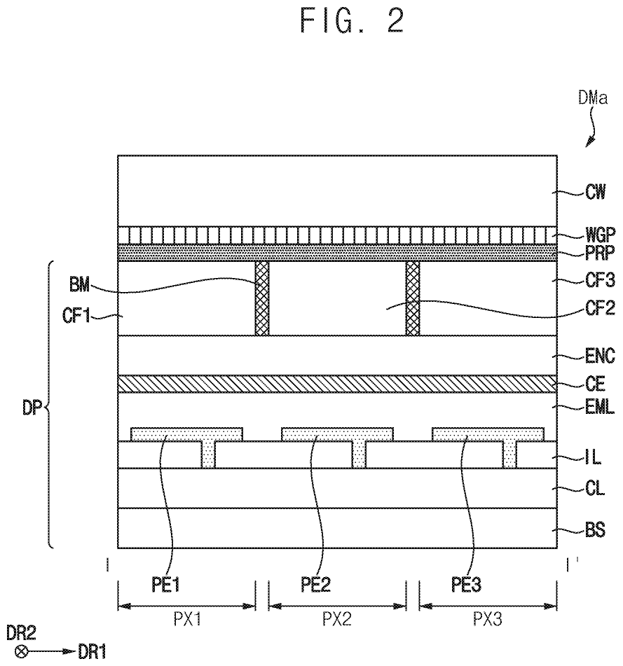

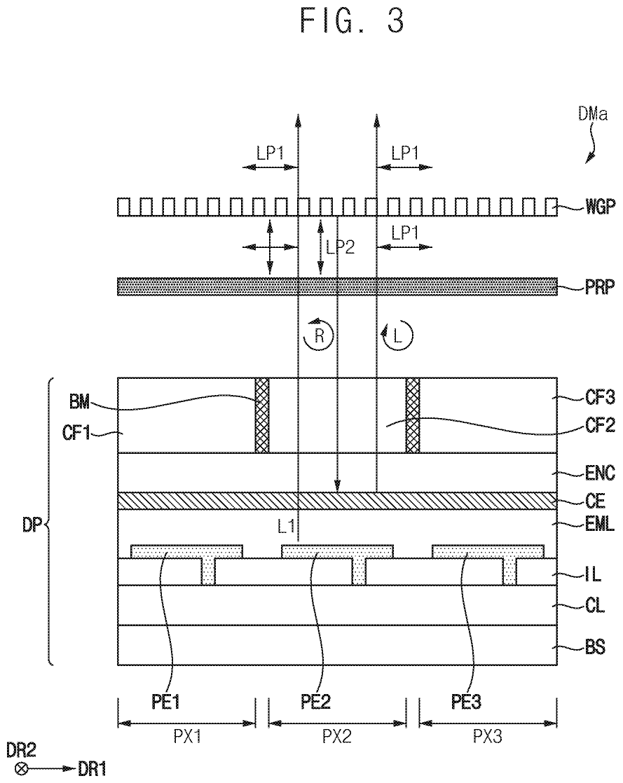

FIG. 2 is a schematic cross-sectional view taken along line I-I′ of FIG. 1. FIG. 3 is a schematic cross-sectional view illustrating recycled light generated in the display module of FIG. 2.

Referring to FIG. 2, the display module DMa according to an embodiment may include a display panel DP, a phase retardation plate PRP, a wire grid polarizer WGP, and a cover window CW. Here, the display panel DP may include a silicon substrate BS, a driving circuit layer CL, an insulating layer IL, first, second, and third pixel electrodes PE1, PE2, and PE3, a light emitting layer EML, a common electrode CE, an encapsulation layer ENC, first, second, and third color filters CF1, CF2, and CF3, and a light blocking layer BM.

As described above, the display module DMa may include the display area DA including the first, second, and third pixel areas PX1, PX2, and PX3 and the peripheral area PA. As the display module DMa may include the display area DA including the first, second, and third pixel areas PX1, PX2, and PX3 and the peripheral area PA, the silicon substrate BS also may include the display area DA including the first, second, and third pixel areas PX1, PX2, and PX3 and the peripheral area PA.

The silicon substrate BS may be a support member for supporting other components of the display module DMa. For example, the silicon substrate BS may be a silicon wafer substrate.

The driving circuit layer CL may be disposed on the silicon substrate BS. The driving circuit layer CL may include various driving elements and lines for driving light emitting elements. For example, the driving circuit layer CL may include various elements such as a transistor, a storage capacitor, a gate line, a data line, and the like within the spirit and the scope of the disclosure.

The insulating layer IL may be disposed on the driving circuit layer CL. The insulating layer IL may prevent contact between the first, second, and third pixel electrodes PE1, PE2, and PE3 and the driving circuit layer CL. The insulating layer IL may include an organic material and/or an inorganic material. For example, the insulating layer IL may include an inorganic material such as silicon oxide (SiOₓ), silicon nitride (SiNₓ), silicon oxynitride (SiOₓN_{y}), and the like within the spirit and the scope of the disclosure. These may be used alone or in combination with each other.

The first, second, and third pixel electrodes PE1, PE2, and PE3 may be disposed on the insulating layer IL. The first pixel electrode PE1 may overlap the first pixel area PX1, the second pixel electrode PE2 may overlap the second pixel area PX2, and the third pixel electrode PE3 may overlap the third pixel area PX3. Each of the first, second, and third pixel electrodes PE1, PE2, and PE3 may be connected to the driving circuit layer CL through a contact hole penetrating the insulating layer IL.

For example, each of the first, second, and third pixel electrodes PE1, PE2, and PE3 may include a metal, an alloy, a metal nitride, a conductive metal oxide, a transparent conductive material, and the like within the spirit and the scope of the disclosure. These may be used alone or in combination with each other. In an embodiment, each of the first, second, and third pixel electrodes PE1, PE2, and PE3 may be an anode electrode. Each of the first, second, and third pixel electrodes PE1, PE2, and PE3 may be a reflective electrode.

The light emitting layer EML may be disposed on the insulating layer IL and the first, second, and third pixel electrodes PE1, PE2, and PE3. The light emitting layer EML may continuously extend over the first, second, and third pixel areas PX1, PX2, and PX3. For example, the light emitting layer EML may include a hole injection layer, a hole transport layer, an organic light emitting layer, an electron injection layer, an electron transport layer, and the like within the spirit and the scope of the disclosure. In an embodiment, the organic light emitting layer may include a light emitting material that emits white light. For example, the white light may be a mixture of blue light, green light, and red light. For example, the white light may be a mixture of blue light and yellow light.

The common electrode CE may be disposed on the light emitting layer EML. The common electrode CE may continuously extend over the first, second, and third pixel areas PX1, PX2 , and PX3. For example, the common electrode CE may include a metal, an alloy, a metal nitride, a conductive metal oxide, a transparent conductive material, and the like within the spirit and the scope of the disclosure. These may be used alone or in combination with each other. In an embodiment, the common electrode CE may be a cathode electrode. The common electrode CE may be a transmissive or semi-transmissive electrode.

In the first pixel area PX1, the first pixel electrode PE1, the light emitting layer EML, and the common electrode CE may constitute a first light emitting element, in the second pixel area PX2, the second pixel electrode PE2, the light emitting layer EML, and the common electrode CE may constitute a second light emitting element, and in the third pixel area PX3, the third pixel electrode PE3, the light emitting layer EML, and the common electrode CE may constitute a third light emitting element.

The encapsulation layer ENC may be disposed on the common electrode CE. The encapsulation layer ENC may continuously extend over the first, second, and third pixel areas PX1, PX2, and PX3. The encapsulation layer ENC may prevent impurities, moisture, and the like from permeating into the first, second, and third light emitting elements from the outside. The encapsulation layer ENC may include at least one inorganic layer and at least one organic layer. For example, the inorganic layer may include silicon oxide, silicon nitride, silicon oxynitride, and the like within the spirit and the scope of the disclosure. These may be used alone or in combination with each other. The organic layer may include a polymer cured material such as polyacrylate.

The first, second, and third color filters CF1, CF2, and CF3 may be disposed on the encapsulation layer ENC. The first color filter CF1 may overlap the first pixel area PX1, the second color filter CF2 may overlap the second pixel area PX2, and the third color filter CF3 may overlap the third pixel area PX3. The first, second, and third color filters CF1, CF2, and CF3 may selectively transmit light of a given wavelength and absorb light of other wavelengths. For example, the first color filter CF1 may transmit red light, the second color filter CF2 may transmit green light, and the third color filter CF3 may transmit blue light. Accordingly, the first pixel area PX1 may emit red light, the second pixel area PX2 may emit green light, and the third pixel area PX3 may emit blue light. However, the configuration is not limited thereto.

The light blocking layer BM may be disposed on the encapsulation layer ENC. The light blocking layer BM may be disposed between the first, second, and third color filters CF1, CF2, and CF3 in a plan view and may not overlap the first, second, and third pixel areas PX1, PX2, and PX3. The light blocking layer BM may block light incident to the light blocking layer BM. Accordingly, color mixing between the first, second, and third pixel areas PX1, PX2, and PX3 may be prevented. For example, the light blocking layer BM may include an organic material and/or an inorganic material containing a black pigment, black dye, and the like within the spirit and the scope of the disclosure.

The phase retardation plate PRP may be disposed on the display panel DP. By way of example, the phase retardation plate PRP may contact the display panel DP. For example, the phase retardation plate PRP may be a film type or a liquid crystal coating type. For example, the phase retardation plate PRP may be separately manufactured and attached to the display panel DP or may be directly formed on the display panel DP through an exposure machine for semiconductor. In an embodiment, the phase retardation plate PRP may include a λ/4 phase retardation plate. The phase retardation plate PRP may delay the phase of incident light by λ/4.

The wire grid polarizer WGP may be disposed on the phase retardation plate PRP. By way of example, the wire grid polarizer WGP may contact the phase retardation plate PRP. The wire grid polarizer WGP may include metal patterns spaced apart from each other at selectable intervals. For example, the metal patterns may be spaced apart from each other in the first direction DR1. For example, the wire grid polarizer WGP may be a film type or a liquid crystal coating type. For example, the wire grid polarizer WGP may be separately manufactured and attached to the display panel DP or may be directly formed on the display panel DP through an exposure machine for semiconductor.

Each of the metal patterns of the wire grid polarizer WGP may extend in parallel in one direction or a direction (for example, the second direction DR2). For example, light incident perpendicularly to the extension direction of the wire grid polarizer WGP may pass through the wire grid polarizer WGP. For example, light incident in parallel to the extension direction of the wire grid polarizer WGP may be reflected by the wire grid polarizer WGP. The wire grid polarizer WGP may include a metal having a relatively high reflectance. For example, the wire grid polarizer WGP may include metals such as aluminum (Al), gold (Au), silver (Ag), copper (Cu), chromium (Cr), iron (Fe), nickel (Ni), and the like within the spirit and the scope of the disclosure. These may be used alone or in combination with each other.

Some of the light emitted from the light emitting layer EML due to the phase retardation plate PRP and the wire grid polarizer WGP may be recycled. For example, referring to FIG. 3, a first light L1 emitted from the light emitting layer EML may pass through the phase retardation plate PRP. The phase of the first light L1 passing through the phase retardation plate PRP may be delayed by λ/4. The first light L1 passing through the phase retardation plate PRP may be incident on the wire grid polarizer WGP. A first linearly polarized light LP1 of the first light L1 incident on the wire grid polarizer WGP may pass through and a second linearly polarized light LP2 of the first light L1 may be reflected. The first linearly polarized light LP1 may be light incident perpendicularly to the extension direction of the wire grid polarizer WGP and the second linearly polarized light LP2 may be incident light parallel to the extension direction of the wire grid polarizer WGP. The second linearly polarized light LP2 reflected from the wire grid polarizer WGP passes through the phase retardation plate PRP and is delayed in phase by λ/4, thereby being converted into a first circularly polarized light R. The first circularly polarized light R may be right circularly polarized light.

The first circularly polarized light R may be incident on the common electrode CE, reflected by the common electrode CE, and converted into a second circularly polarized light L. The second circularly polarized light L may be left circularly polarized light. The second circularly polarized light L may be converted into the first linearly polarized light LP1 by passing through the phase retardation plate PRP and being delayed in phase by λ/4. The first linearly polarized light LP1 may be incident on the wire grid polarizer WGP and pass through the wire grid polarizer WGP.

As a result, as the phase retardation plate RPP and the wire grid polarizer WGP are disposed on the display panel DP, some of the light emitted from the light emitting layer EML may be recycled without being blocked. An absorption polarizer that blocks some of the light emitted from the light emitting layer EML may not be disposed on the display panel DP. For example, the phase retardation plate PRP and the wire grid polarizer WGP may replace the absorption polarizer. Accordingly, light efficiency of the display module DMa may be improved.

Referring back to FIG. 2, the cover window CW may be disposed on the wire grid polarizer WGP. The cover window CW may protect the display panel DP. For example, the cover window CW may include reinforced glass or reinforced plastic. For example, the cover window CW may be formed of a single layer or may have a structure in which functional layers are stacked each other.

The display module DMa according to an embodiment may be a display device that displays an image. For example, the display module DMa may be a display device such as an organic light emitting display device, a liquid crystal display device, an organic light emitting diode on silicon substrate (OLEDos), a liquid crystal on silicon substrate (LCos), or a light emitting diode on silicon substrate (LEDos). In an embodiment, the display module DMa may be a display device such as the OLEDos.

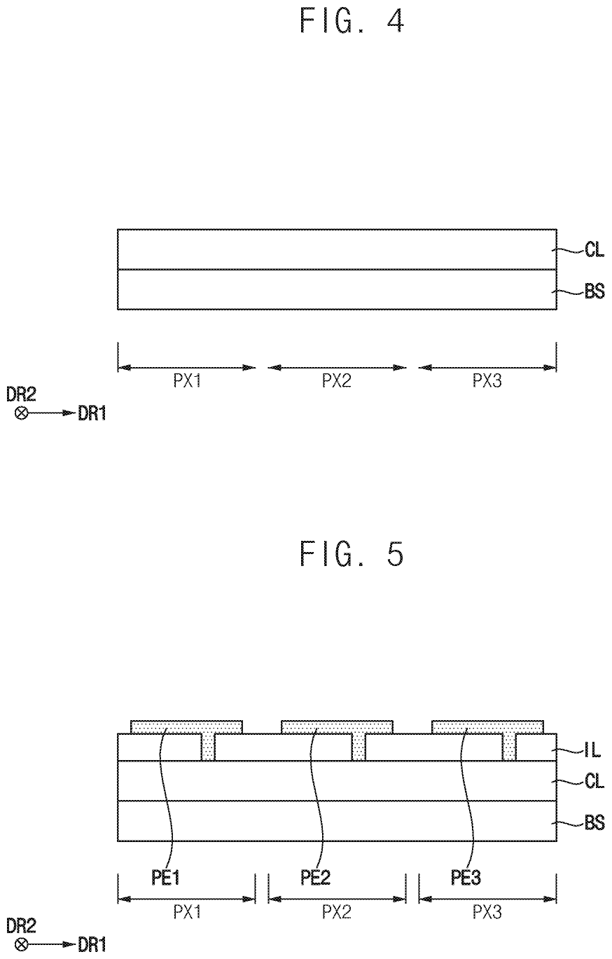

FIGS. 4, 5, 6, 7, and 8 are schematic cross-sectional views for explaining a manufacturing method of the display module of FIG. 2.

Referring to FIG. 4, the driving circuit layer CL may be formed on the silicon substrate BS. For example, the driving circuit layer CL may include various driving elements and lines.

Referring to FIG. 5, the insulating layer IL may be formed on the driving circuit layer CL. For example, the insulating layer IL may be formed using an organic material and/or an inorganic material.

The first, second, and third pixel electrodes PE1, PE2, and PE3 may be formed on the insulating layer IL. The first pixel electrode PE1 may be formed in the first pixel area PX1, the second pixel electrode PE2 may be formed in the second pixel area PX2, and the third pixel electrode PE3 may be formed in the third pixel area PX3. Each of the first, second, and third pixel electrodes PE1, PE2, and PE3 may be connected to the driving circuit layer CL through a contact hole formed by removing a part of the insulating layer IL.

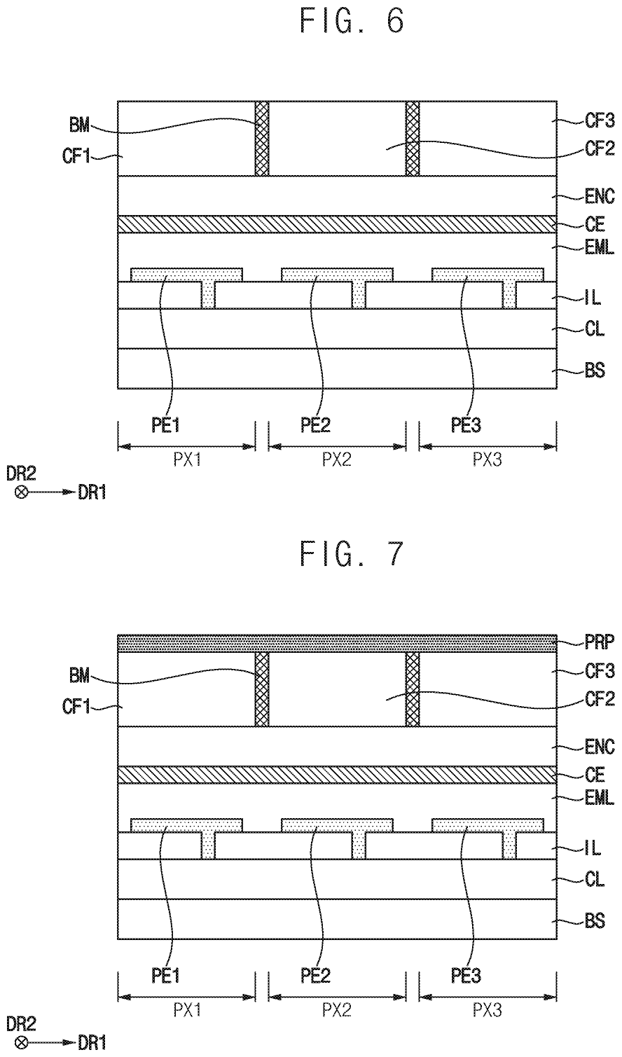

Referring to FIG. 6, the light emitting layer EML may be formed on the insulating layer IL and the first, second, and third pixel electrodes PE1, PE2, and PE3. The light emitting layer EML may be formed entirely over the first, second, and third pixel areas PX1, PX2, and PX3. For example, the light emitting layer EML may be formed using a light emitting material that emits white light.

The common electrode CE may be formed on the light emitting layer EML. The common electrode CE may be formed entirely over the first, second, and third pixel areas PX1, PX2, and PX3. The encapsulation layer ENC may be formed on the common electrode CE. The encapsulation layer ENC may be formed entirely over the first, second, and third pixel areas PX1, PX2, and PX3. For example, the encapsulation layer ENC may include at least one inorganic layer and at least one organic layer.

The first, second, and third color filters CF1, CF2, and CF3 may be formed on the encapsulation layer ENC. The first color filter CF1 may be formed in the first pixel area PX1, the second color filter CF2 may be formed in the second pixel area PX2, and the third color filter CF3 may be formed in the third pixel area PX3.

For example, the first color filter CF1 may be a red color filter that transmits red light. The first color filter CF1 may be formed of a red pigment and/or a color filter composition including the red pigment.

For example, the second color filter CF2 may be a green color filter that transmits green light. The second color filter CF2 may be formed from a green pigment and/or a color filter composition including the green pigment.

For example, the third color filter CF3 may be a blue color filter that transmits blue light. The third color filter CF3 may be formed from a blue pigment and/or a color filter composition including the blue pigment.

The light blocking layer BM may be formed on the encapsulation layer ENC. The light blocking layer BM may be formed between the first, second, and third color filters CF1, CF2, and CF3 in the plan view. For example, the light blocking layer BM may be formed using an organic material and/or an inorganic material containing a light blocking material.

Referring to FIG. 7, the phase retardation plate PRP may be formed on the first, second, and third color filters CF1, CF2, and CF3 and the light blocking layer BM. In an embodiment, the phase retardation plate PRP may be formed through an exposure machine for semiconductor. In an embodiment, the phase retardation plate PRP may be separately manufactured and attached on the first, second, and third color filters CF1, CF2, and CF3 and the light blocking layer BM.

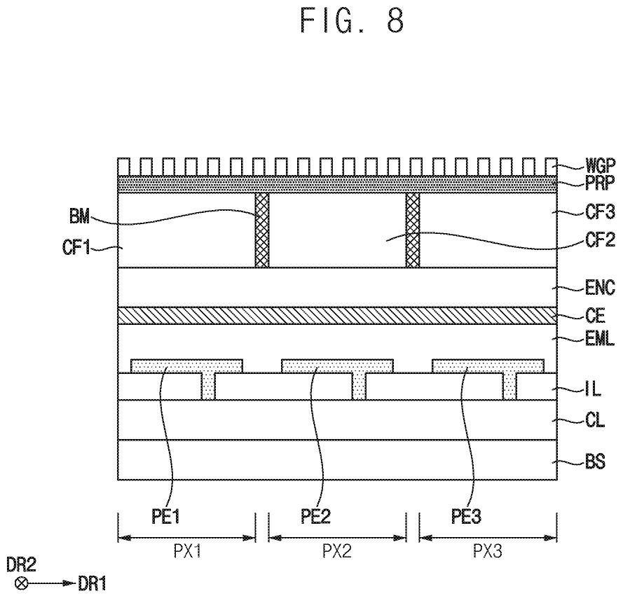

Referring to FIG. 8, the wire grid polarizer WGP may be formed on the phase retardation plate PRP. In an embodiment, the wire grid polarizer WGP may be formed through an exposure machine for semiconductor. In an embodiment, the wire grid polarizer WGP may be separately manufactured and attached to the phase retardation plate PRP. For example, the wire grid polarizer WGP may be formed using a metal having a relatively high reflectance.

Referring back to FIG. 2, the cover window CW may be attached to the wire grid polarizer WGP. For example, the cover window CW may include reinforced glass or reinforced plastic.

Accordingly, the display module DMa illustrated in FIG. 2 may be manufactured.

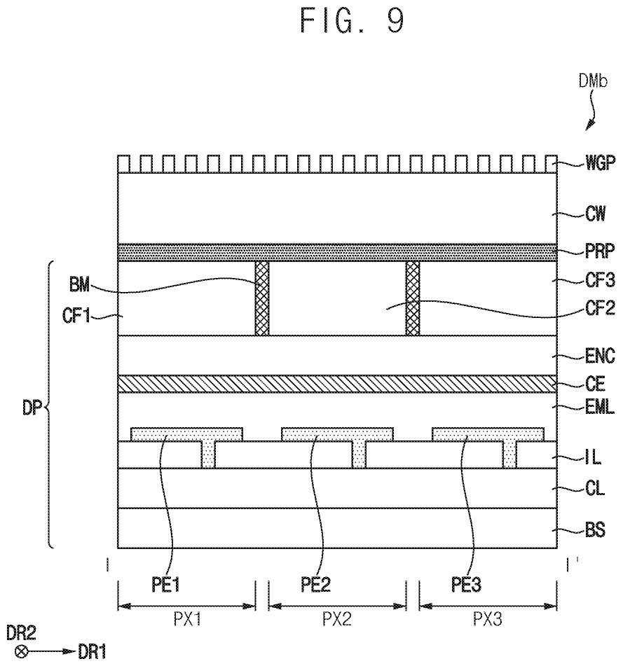

FIGS. 9, 10, and 11 are schematic cross-sectional views illustrating a display module according to an embodiment.

Referring to FIG. 9, a display module DMb according to an embodiment may include a display panel DP, a phase retardation plate PRP, a wire grid polarizer WGP, and a cover window CW. Here, the display panel DP may include a silicon substrate BS, a driving circuit layer CL, an insulating layer IL, first, second, and third pixel electrodes PE1, PE2, and PE3, a light emitting layer EML, a common electrode CE, an encapsulation layer ENC, first, second, and third color filters CF1, CF2, and CF3, and a light blocking layer BM. However, the display module DMb described with reference to FIG. 9 may be substantially the same as or similar to the display module DMa described with reference to FIG. 2 except for the disposition order of the phase retardation plate PRP, the wire gride polarizer WGP, and the cover window CW. In the following, redundant descriptions are omitted or simplified.

The phase retardation plate PRP may be disposed on the display panel DP, and the cover window CW may be disposed on the phase retardation plate PRP. In an embodiment, the cover window CW may be disposed between the phase retardation plate PRP and the wire grid polarizer WGP. For example, the phase retardation plate PRP, the cover window CW, and the wire grid polarizer WGP may be sequentially disposed on the display panel DP. By way of example, lower and upper surfaces of the phase retardation plate PRP may contact the display panel DP and the cover window CW, respectively, and the lower surface of the wire grid polarizer WGP may contact the cover window CW.

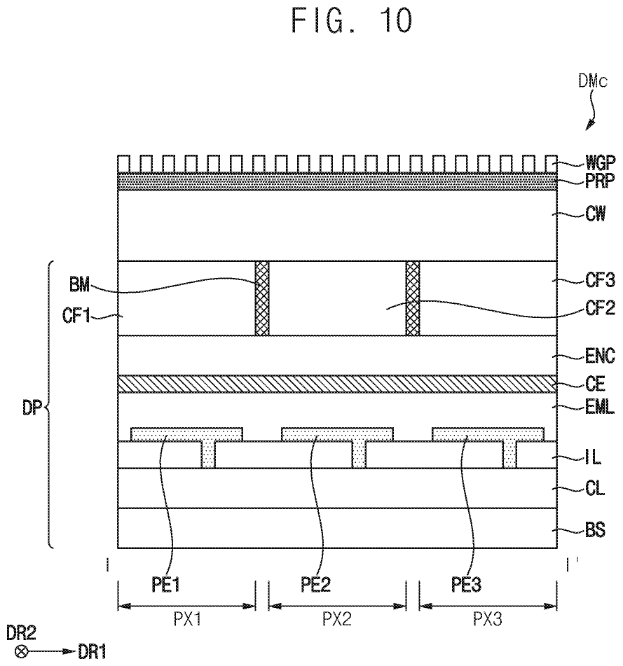

Referring to FIG. 10, a display module DMc according to an embodiment may include a display panel DP, a phase retardation plate PRP, a wire grid polarizer WGP, and a cover window CW. However, the display module DMc described with reference to FIG. 10 may be substantially the same as or similar to the display module DMa described with reference to FIG. 2 except for the disposition order of the phase retardation plate PRP, the wire gride polarizer WGP, and the cover window CW. In the following, redundant descriptions are omitted or simplified.

The cover window CW may be disposed on the display panel DP, and the phase retardation plate PRP may be disposed on the cover window CW. In an embodiment, the cover window CW may be disposed between the display panel DP and the phase retardation plate PRP. For example, the cover window CW, the phase retardation plate PRP, and the wire grid polarizer WGP may be sequentially disposed on the display panel DP. By way of example, a lower surface of the phase retardation plate PRP may contact the cover window CW, and a lower surface of the wire grid polarizer WGP may contact the phase retardation plate PRP.

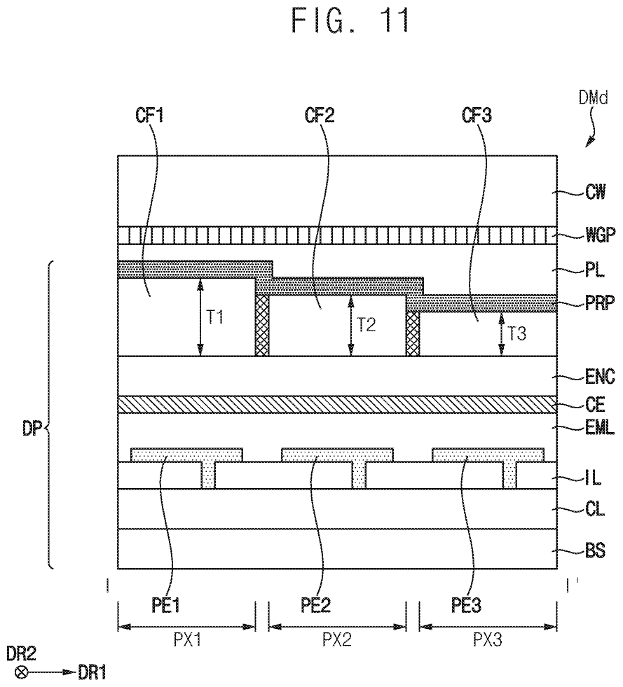

Referring to FIG. 11, a display module DMd according to an embodiment may include a display panel DP, a phase retardation plate PRP, a planarization layer PL, a wire grid polarizer WGP, and a cover window CW. Here, the display panel DP may include a silicon substrate BS, a driving circuit layer CL, an insulating layer IL, first, second, and third pixel electrodes PE1, PE2, and PE3, a light emitting layer EML, a common electrode CE, an encapsulation layer ENC, first, second, and third color filters CF1, CF2, and CF3, and a light blocking layer BM. However, the display module DMd described with reference to FIG. 9 may be substantially the same as or similar to the display module DMa described with reference to FIG. 2 except for the first, second, and third color filter CF1, CF2, and CF3 and the planarization layer PL. In the following, redundant descriptions are omitted or simplified.

The first, second, and third color filters CF1, CF2, and CF3 may be disposed on the encapsulation layer ENC. The first color filter CF1 may overlap the first pixel area PX1, the second color filter CF2 may overlap the second pixel area PX2, and the third color filter CF3 may overlap the third pixel area PX3.

The first, second, and third color filters CF1, CF2, and CF3 may have different thicknesses. For example, a first thickness T1 of the first color filter CF1 may be thicker than a second thickness T2 of the second color filter CF2, and the second thickness T2 of the second color filter CF2 may be thicker than a third thickness T3 of the third color filter CF3. In an embodiment, the second thickness T2 may be in a range of about 1.1 to about 1.3 times the third thickness T3, and the first thickness T1 may be in a range of about 1.3 to about 1.5 times the third thickness T3. In case that the second thickness T2 is less than about 1.1 times or greater than about 1.4 times the third thickness T3, wavelength dispersion of the phase retardation plate PRP duet to a difference in wavelength of light passing through the first, second, and third color filters CF1, CF2, and CF3 may not be removed. In case that the first thickness T1 is less than about 1.3 times or greater than about 1.5 times the third thickness T3, wavelength dispersion of the phase retardation plate PRP due to a difference in wavelength of light passing through the first, second, and third color filters CF1, CF2, and CF3 may not be removed.

The phase retardation plate PRP may be disposed on the first, second, and third color filters CF1, CF2, and CF3. By way of example, lower surface of the phase retardation plate PRP may contact the display panel DP. The phase retardation plate PRP may be disposed along the profiles of the first, second, and third color filters CF1, CF2, and CF3. For example, the phase retardation plate PRP may continuously extend over the first, second, and third pixel areas PX1, PX2, and PX3.

The planarization layer PL may be disposed on the phase retardation plate PRP. The planarization layer PL may have a substantially flat upper surface. For example, the planarization layer PL may include an inorganic material and/or an organic material.

The wire grid polarizer WGP may be disposed on the planarization layer PL, and the cover window CW may be disposed on the wire grid polarizer WGP. By way of example, lower and upper surfaces of the wire grid polarizer WGP may contact the planarization layer PL and the cover window CW, respectively.

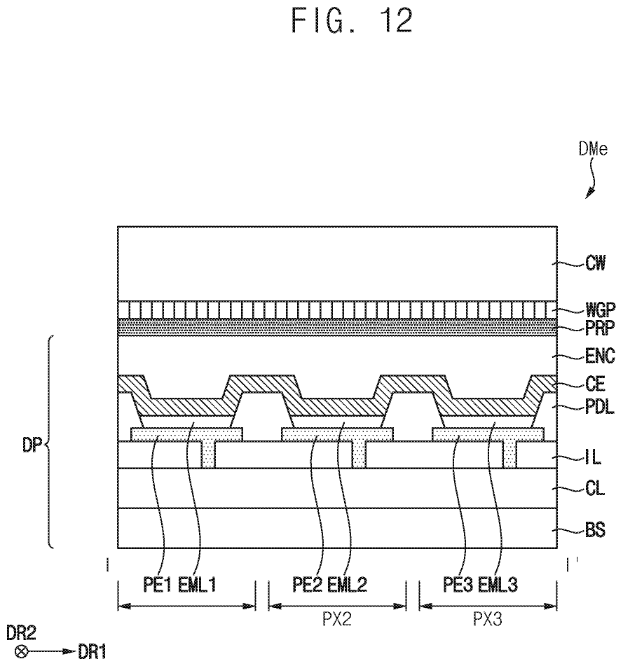

FIGS. 12, 13, and 14 are schematic cross-sectional views illustrating a display module according to an embodiment.

Referring to FIG. 12, a display module DMe according to an embodiment may include a display panel DP, a phase retardation plate PRP, a wire grid polarizer WGP, and a cover window CW. Here, the display panel DP may include a silicon substrate BS, a driving circuit layer CL, an insulating layer IL, first, second, and third pixel electrodes PE1, PE2, and PE3, a pixel defining layer PDL, first, second, and third light emitting layers EML1, EML2, and EML3, a common electrode CE, and an encapsulation layer ENC. However, the display module DMe described with reference to FIG. 12 may be substantially the same as or similar to the display module DMa described with reference to FIG. 2 except that the color filters CF1, CF2 and CF3 and the light blocking layer BM are not disposed. In the following, redundant descriptions are omitted or simplified.

The pixel defining layer PDL may be disposed on the insulating layer IL and the first, second, and third pixel electrodes PE1, PE2, and PE3. An opening exposing at least a part of the upper surface of each of the first, second, and third pixel electrodes PE1, PE2, and PE3 may be defined in the pixel defining layer PDL. The pixel defining layer PDL may include an inorganic material and/or an organic material. For example, the pixel defining layer PDL may include phenolic resin, polyacrylates resin, polyimides rein, polyamides resin, siloxane resin, epoxy resin, and the like within the spirit and the scope of the disclosure. These may be used alone or in combination with each other.

The first light emitting layer EML1 may be disposed on the first pixel electrode PE1, the second light emitting layer EML2 may be disposed on the second pixel electrode PE2, and the third light emitting layer may be disposed on the third pixel electrode PE3. For example, the first light emitting layer EML1 may overlap the first pixel area PX1, the second light emitting layer EML2 may overlap the second pixel area PX2, and the third light emitting layer EML3 may overlap the third pixel area PX3. Each of the first, second, and third light emitting layers EML1, EML2, and EML3 may include a light emitting material that emits light of a selectable color. For example, the first light emitting layer EML1 may include a light emitting material that emits red light, the second light emitting layer EML2 may include a light emitting material that emits green light, and the third light emitting layer EML3 may include a light emitting material that emits blue light. Functional layers (for example, a hole injection layer, a hole transport layer, an electron injection layer, an electron transport layer, and the like) may be disposed below and/or above the first, second, and third light emitting layers EML1, EML2, and EML3.

The common electrode CE may be disposed on the first, second, and third light emitting layers EML1, EML2, and EML3 and the pixel defining layer PDL, and the encapsulation layer ENC may be disposed on the common electrode CE.

The phase retardation plate PRP, the wire grid polarizer WGP, and the cover window CW may be sequentially disposed on the display panel DP. By way of example, the phase retardation plate RPP, the wire grid polarizer WGP, and the cover window CW may be sequentially disposed on the encapsulation layer ENC. For example, the phase retardation plate PRP and the wire grid polarizer WGP may be disposed between the display panel DP and the cover window CW.

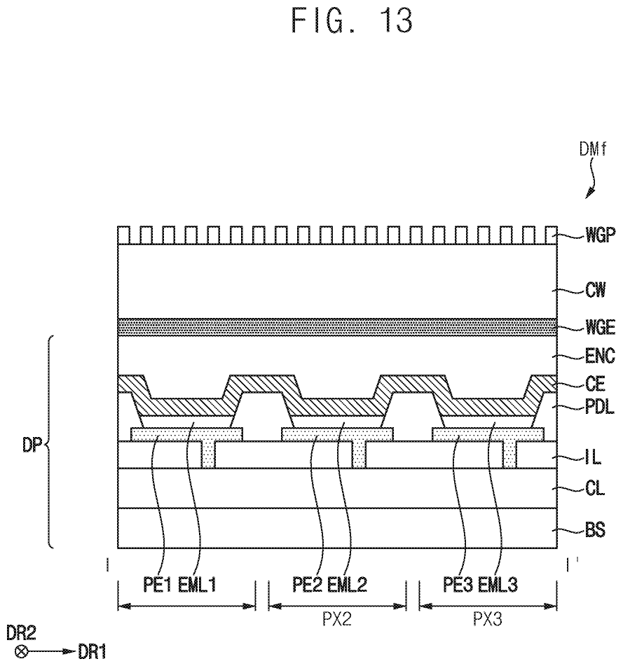

Referring to FIG. 13, a display module DMf according to an embodiment may include a display panel DP, a phase retardation plate PRP, a wire grid polarizer WGP, and a cover window CW. However, the display module DMf described with reference to FIG. 13 may be substantially the same or similar to the display module DMe described with reference to FIG. 12 except for the disposition order of the phase retardation plate PRP, the wire gride polarizer WGP, and the cover window CW. In the following, redundant descriptions are omitted or simplified.

The phase retardation plate PRP may be disposed on the display panel DP, and the cover window CW may be disposed on the phase retardation plate PRP. In an embodiment, the cover window CW may be disposed between the phase retardation plate PRP and the wire grid polarizer WGP. For example, the phase retardation plate PRP, the cover window CW, and the wire grid polarizer WGP may be sequentially disposed on the display panel DP. By way of example, lower and upper surfaces of the phase retardation plate PRP may contact the display panel DP and the cover window CW, respectively, and lower surface of the wire grid polarizer WGP may contact the cover window CW.

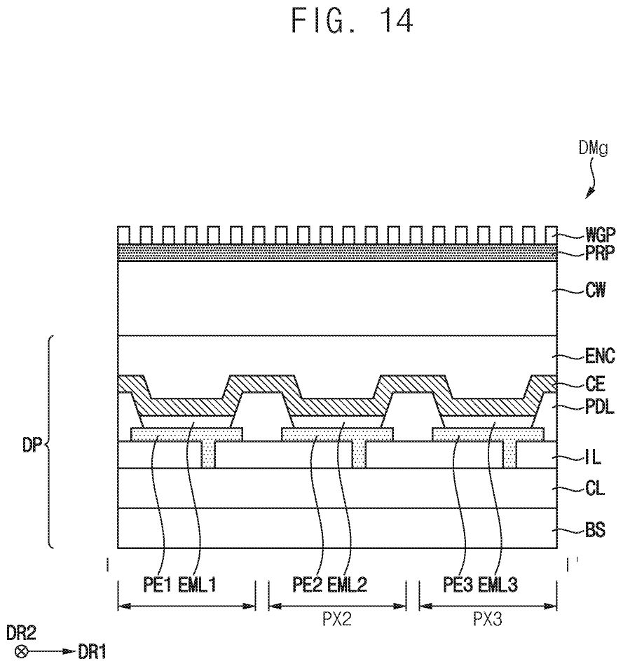

Referring to FIG. 14, a display module DMg according to an embodiment may include a display panel DP, a phase retardation plate PRP, a wire grid polarizer WGP, and a cover window CW. However, the display module DMg described with reference to FIG. 14 may be substantially the same or similar to the display module DMe described with reference to FIG. 12 except for the disposition order of the phase retardation plate PRP, the wire gride polarizer WGP, and the cover window CW. In the following, redundant descriptions are omitted or simplified.

The cover window CW may be disposed on the display panel DP, and the phase retardation plate PRP may be disposed on the cover window CW. In an embodiment, the cover window CW may be disposed between the display panel DP and the phase retardation plate PRP. For example, the cover window CW, the phase retardation plate PRP, and the wire grid polarizer WGP may be sequentially disposed on the display panel DP. By way of example, lower surface of the phase retardation plate PRP may contact the cover window CW, and lower surface of the wire grid polarizer WGP may contact the phase retardation plate PRP.

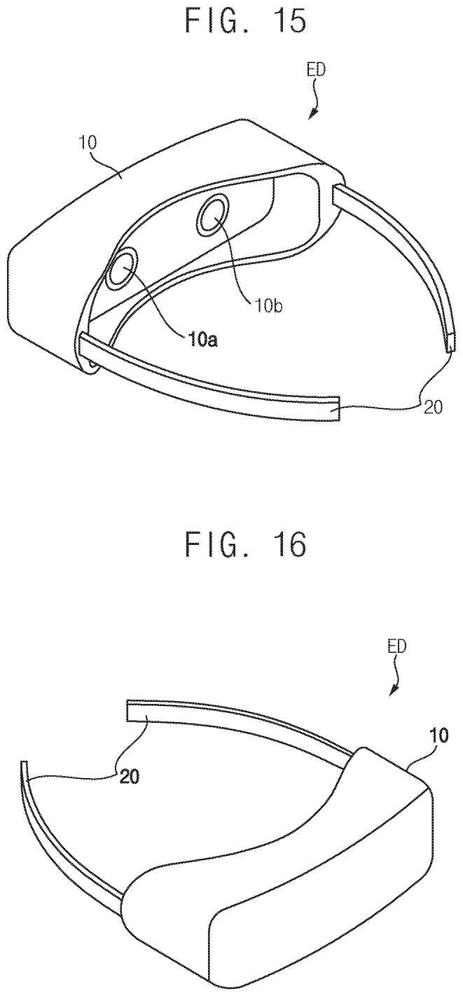

FIGS. 15 and 16 are perspective views illustrating an electronic device according to an embodiment.

Referring to FIGS. 15 and 16, an electronic device ED according to an embodiment may include a display module accommodating portion 10, a first eyepiece 10a, a second eyepiece 10b, and a glasses frame leg 20. For example, the electronic device ED according to an embodiment may be implemented as a head mounted display. Therefore, hereinafter, the electronic device ED will be described as an example of the head mounted display.

The display module accommodating portion 10 may include a display module for displaying an image and an optical member for providing the image displayed on the display module to the first and second eyepiece 10a and 10b. Here, the display module may correspond to the display modules DMa, DMb, DMc, DMd, DMe, DMf, and DMg illustrated in FIGS. 2 and 9, 10, 11, 12, 13, and 14. A detailed description of the display module accommodating portion 10 will be described later.

The first and second eyepiece 10a and 10b may be disposed on one surface or a surface of the display module accommodating portion 10. By way of example, the first and second eyepiece 10a and 10b may be disposed on the lower surface of the display module accommodating portion 10. For example, the first eyepiece 10a may be a left eye lens where the user's left eye is located, and the second eyepiece 10b may be a right eye lens where the user's right eye is located. Through the first and second eyepieces 10a and 10b, the user may see an image displayed by the display module of the display module accommodating portion 10.

The electronic device ED may provide an image displayed on the display module of the display module accommodating portion 10 to the user through the first and second eyepiece 10a and 10b. As a result, the electronic device ED may provide a virtual image displayed by the display module of the display module accommodating portion 10 to the user. For example, the electronic device ED may implement virtual reality (VR).

The glasses frame leg 20 may be configured so that the user can readily put it on or take it off. However, the configuration is not limited thereto, and the electronic device ED may include a head mounted band that can be mounted on the head instead of the glasses frame leg 20.

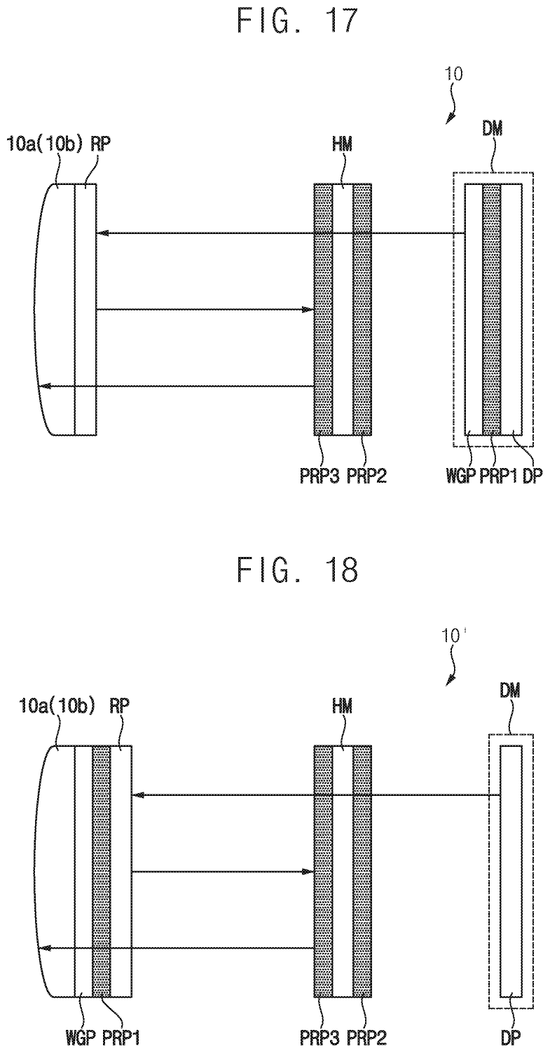

FIG. 17 is a side view illustrating an example of a display module accommodating portion of the electronic device of FIGS. 15 and 16. FIG. 18 is a side view illustrating another example of a display module accommodating portion of the electronic device of FIGS. 15 and 16. For example, FIGS. 17 and 18 illustrate the configuration of the display module accommodating portion 10 for providing images to the first and second eyepiece 10a and 10b of the electronic device ED of FIGS. 15 and 16.

Referring to FIGS. 17 and 18, the display module accommodation portion 10 of the electronic device ED according to an embodiment may include the display panel DP, a first phase retardation plate PRP1, a wire grid polarizer WGP, a second phase retardation plate PRP2, a half mirror HM, a third phase retardation plate PRP3, and a reflective polarizer RP.

The wire grid polarizer WGP may be disposed between the display panel DP and the eyepieces 10a and 10b. The first phase retardation plate PRP1 may be disposed between the wire grid polarizer WGP and the display panel DP and may be adjacent to the wire grid polarizer WGP. The first phase retardation plate PRP1 and the wire grid polarizer WGP illustrated in FIGS. 17 and 18 may correspond to the phase retardation plate PRP and the wire grid polarizer WGP illustrated in FIGS. 2 and 9, 10, 11, 12, 13, and 14, respectively.

In an embodiment, as illustrated in FIG. 17, the first phase retardation plate PRP1 may contact one surface or a surface of the display panel DP, and the wire grid polarizer WGP may contact one surface or a surface of the first phase retardation plate PRP1, and the reflective polarizer RP may contact one surface or a surface of the eyepiece lenses 10a and 10b. The display panel DP, the first phase retardation plate PRP1, the wire grid polarizer WGP, and a cover window (for example, the cover window CW of FIG. 2) may constitute a display module DM. The display module DM may correspond to the display module DMa illustrated in FIG. 2. For example, the display module DM may correspond to the display modules DMb, DMc, DMd, DMe, DMf, and DMg illustrated in FIGS. 9, 10, 11, 12, 13, and 14.

In an embodiment, as illustrated in FIG. 18, the wire grid polarizer WGP may contact the other surface of the eyepieces 10a and 10b, and the first phase retardation plate PRP1 may be disposed between the wire grid polarizer WGP and the reflective polarizer RP. By way of example, one surface or a surface of the first phase retardation plate PRP1 may contact the wire grid polarizer WGP and the other surface of the first phase retardation plate PRP1 may contact the reflective polarizer RP. The display panel DP and the cover window constitute the display module DM, and the display module DM may not include the first phase retardation plate PRP1 and the wire grid polarizer WGP.

The second phase retardation plate PRP2 may be disposed between the display panel DP and the eyepieces 10a and 10b. By way of example, the second phase retardation plate PRP2 may contact one surface or a surface of the half mirror HM. In an embodiment, the second phase delay plate PRP2 may include a λ/4 phase delay plate. The second phase retardation plate PRP2 may delay the phase of incident light by λ/4.

The half mirror HM may be disposed between the second phase retardation plate PRP2 and the third phase retardation plate PRP3. By way of example, one surface or a surface of the half mirror HM may contact the second phase retardation plate PRP2, and the other surface of the half mirror HM may contact the third phase retardation plate PRP3.

The half mirror HM may include a semi-transmissive plate that transmits a part of light and reflects another part of light. For example, the half mirror HM may include glass having a semi-transmissive metal film formed on one surface or a surface thereof. For example, the semi-transmissive metal film may include a semi-transmissive metal material such as magnesium (Mg), silver (Ag), an alloy containing magnesium (Mg) and silver (Ag), and the like within the spirit and the scope of the disclosure. These may be used alone or in combination with each other.

The third phase retardation plate PRP3 may contact the other surface of the half mirror HM. In an embodiment, the third phase delay plate PRP3 may include a λ/4 phase delay plate. The third phase retardation plate PRP3 may delay the phase of incident light by λ/4.

The reflective polarizer RP may be disposed between the eyepieces 10a and 10b and the second phase retardation plate PRP2. By way of example, the reflective polarizer RP may be disposed between the eyepieces 10a and 10b and the third phase retardation plate PRP3. The reflective polarizer RP may transmit first linearly polarized light vibrating in a vertical direction and reflect second linearly polarized light vibrating in a horizontal direction. For example, the reflective polarizer RP may be an advanced polarizing film (APF) or a dual bright enhanced film (DBEF). However, the configuration is not limited thereto.

The eyepieces 10a and 10b may be convex lenses or fresnel lenses. Since a polarizer (for example, the reflective polarizer RP or the wire grid polarizer WGP) contacts one surface or a surface of the eyepiece 10a and 10b, the one surface or a surface of the eyepiece 10a and 10b may be formed flat to facilitate contact with the polarizer. A convex lens or a fresnel lens may be formed on the other surfaces of the eyepieces 10a and 10b.

As the display module accommodating portion 10 may include the above components, the image may be provided to the user through the eyepieces 10a and 10b. For example, some of the light emitted from the display module DM may pass through the second phase retardation plate PRP2, the half mirror HM, and the third phase retardation plate PRP3 and be incident on the reflective polarizer RP, some of the light incident on the reflective polarizer RP may be reflected and be incident on the half mirror HM, and some of the light incident on the half mirror HM may be reflected and be incident on the eyepieces 10a and 10b. Accordingly, the image displayed on the display module DM may be provided to the user.

The electronic device of the disclosure may be implemented as a head-mounted display having various forms. For example, a head-mounted display may implement virtual reality or augmented reality.

The foregoing is illustrative of embodiments and is not to be construed as limiting thereof. Although embodiments have been described, those skilled in the art will readily appreciate that many modifications are possible in the embodiments without materially departing from the novel teachings and advantages of the disclosure. Accordingly, all such modifications are intended to be included within the scope of the disclosure and as defined in the claims. Therefore, it is to be understood that the foregoing is illustrative of various embodiments and is not to be construed as limited to the disclosed embodiments, and that modifications to the disclosed embodiments, as well as other embodiments, are intended to be included within the scope of the appended claims.

What is claimed is:

1. A display module comprising:
a display panel including:
a silicon substrate including pixel areas;
a driving circuit layer disposed on the silicon substrate;
a light emitting layer disposed on the driving circuit layer and extending over the pixel areas continuously; and
a color filter disposed in the pixel areas on the light emitting layer;
a phase retardation plate disposed on the display panel; and
a wire grid polarizer disposed on the phase retardation plate and including metal patterns spaced apart from each other at selectable intervals.

2. The display module of claim 1, wherein the phase retardation plate includes a λ/4 phase retardation plate.

3. The display module of claim 1, further comprising:
a cover window disposed on the display panel.

4. The display module of claim 3, wherein the cover window is disposed on the wire grid polarizer.

5. The display module of claim 3, wherein the cover window is disposed between the phase retardation plate and the wire grid polarizer.

6. The display module of claim 3, wherein the cover window is disposed between the color filter and the phase retardation plate.

7. The display module of claim 1, wherein the color filter includes:
a first color filter disposed in a first pixel area among the pixel areas and that transmits red light;
a second color filter disposed in a second pixel area among the pixel areas and that transmits green light; and
a third color filter disposed in a third pixel area among the pixel areas and that transmits blue light.

8. The display module of claim 7, further comprising:
a planarization layer disposed between the phase retardation plate and the wire grid polarizer,
wherein a first thickness of the first color filter is thicker than a second thickness of the second color filter and the second thickness of the second color filter is thicker than a third thickness of the third color filter.

9. The display module of claim 8, wherein
the second thickness of the second color filter is in a range of about 1.1 to about 1.1 times the third thickness of the third color filter, and
the first thickness of the first color filter is in a range of about 1.3 to about 1.5 times the third thickness. of the third color filter.

10. The display module of claim 1, wherein the light emitting layer includes a light emitting material that emits white light.

11. A display module comprising:
a display panel including:
a silicon substrate including a first pixel area, a second pixel area, and a third pixel area;
a driving circuit layer disposed on the silicon substrate; and
a first light emitting layer, a second light emitting layer, and a third light emitting layer disposed in the first pixel area, the second pixel area, and the third pixel area, on the driving circuit layer, respectively;
a phase retardation plate disposed on the display panel; and
a wire grid polarizer disposed on the phase retardation plate and including metal patterns spaced apart from each other at selectable intervals.

12. The display module of claim 11, wherein the phase retardation plate includes a λ/4 phase retardation plate.

13. The display module of claim 11, further comprising:
a cover window disposed on the display panel.

14. The display module of claim 13, wherein the cover window is disposed on the wire grid polarizer.

15. The display module of claim 13, wherein the cover window is disposed between the phase retardation plate and the wire grid polarizer.

16. The display module of claim 13, wherein the cover window is disposed between the display panel and the phase retardation plate.

17. The display module of claim 11, wherein
the first light emitting layer includes a light emitting material that emits red light,
the second light emitting layer includes a light emitting material that emits green light, and
the third light emitting layer includes a light emitting material that emits blue light.

18. An electric device comprising:
an eyepiece; and
a display module accommodating portion including a display module that provides an image to the eyepiece,
wherein the display module accommodating portion includes:
a display panel including:
a silicon substrate including pixel areas;
a driving circuit layer disposed on the silicon substrate;
a light emitting layer disposed on the driving circuit layer and extending over the pixel areas continuously; and
a color filter disposed in the pixel areas on the light emitting layer;
a wire grid polarizer disposed between the eyepiece and the display panel and including metal patterns spaced apart from each other at selectable intervals;
a first λ/4 phase retardation plate disposed between the wire grid polarizer and the display panel and adjacent to the wire grid polarizer;
a second λ/4 phase retardation plate disposed between the display panel and the eyepiece;
a reflective polarizer disposed between the second λ/4 phase retardation plate and the eyepiece;
a third λ/4 phase retardation plate disposed between the reflective polarizer and the second λ/4 phase retardation plate; and
a semi-transmissive plate disposed between the second λ/4 phase retardation plate and the third λ/4 phase retardation plate.

19. The electric device of claim 18, wherein
the first λ/4 phase retardation plate contacts a surface of the display panel,
the wire grid polarizer contacts a surface of the first λ/4 phase retardation plate, and
the reflective polarizer contacts a surface of the display panel.

20. The electric device of claim 18, wherein
the wire grid polarizer contacts a surface of the eyepiece, and
the first λ/4 phase retardation plate is disposed between the wire grid polarizer and the reflective polarizer.
